(19) United States
(12) Patent Application Publication
(10) Pub. No.: US 2014/0103437 A1
(43) Pub. Date: Apr. 17, 2014

(54) Random Doping Fluctuation Resistant FinFET

(71) Applicants: Gold Standard Simulations Ltd., Glasgow (GB); Semi Solutions LLC, Los Gatos, CA (US)

(72) Inventors: Ashok K. Kapoor, Palo Alto, CA (US); Robert J. Strain, San Jose, CA (US)

(73) Assignees: GOLD STANDARD SIMULATIONS LTD., Glasgow (GB); SEMI SOLUTIONS LLC, Los Gatos, CA (US)

(21) Appl. No.: 14/051,163

(22) Filed: Oct. 10, 2013

Related U.S. Application Data
(60) Provisional application No. 61/713,632, filed on Oct. 15, 2012.

(51) Int. Cl. H01L 29/78; H01L 29/66

(52) U.S. Cl. CPC H01L 29/785; H01L 29/66795
USPC 257/347; 438/153

(57) ABSTRACT

An improved fin field-effect transistor (FinFET) is built on a compound fin, which has a doped core and lightly doped epitaxial channel region between that core and the gate dielectric. The improved structure reduces FinFET random doping fluctuations when doping is used to control threshold voltage. Further, the transistor design affords better source and drain conductance when compared to prior art FinFETs. Three representative embodiments of the key structure are described in detail.

### CROSS-REFERENCE TO RELATED APPLICATIONS

This application claims the benefit of U.S. Provisional Patent Application No. 61/713,632 filed Oct. 15, 2012.

### BACKGROUND OF THE INVENTION

1. Field of the Invention

The present invention generally relates to the manufacturing of metal-oxide-semiconductor field effect transistors (MOSFETs), and more particularly to FinFETs and other transistors based on an active region perpendicular to the plane of the silicon wafer. Even more specifically, this invention deals with those instances where random variations of the threshold voltages of such transistors adversely affect integrated circuit performance.

2. Prior Art

Transistors built on a silicon fin were demonstrated as early as 1991 (Hisamoto, D., et al., “Impact of the vertical SOI ‘DELTA’ structure on planar device technology,” Electron Devices, IEEE Transactions on, vol. 38, no. 6, pp. 1419-1424, June 1991) with the goal of achieving better transconductance and superior On/Off ratios. The fin structure was identified for its superior short channel performance in the late 1990's (Xuejue Huang, et al., “Sub 50-nm FinFET: PMOS,” Electron Devices Meeting, 1999. IEDM Technical Digest. International, pp. 67-70, Dec. 1999) when the name FinFET came to represent this class of transistor. The absence of doping ions in FinFETs promised the absence of random variation in threshold voltage (_{σ}V_{T}) attributable to random doping fluctuations (Meng-Hsueh Chiang, et al., “Random Dopant Fluctuation in Limited-Width FinFET Technologies,” Electron Devices, IEEE Transactions on, vol. 54, no. 8, pp. 2055-2060, Aug. 2007), but that promise fails when the fin is doped. For conventional planar transistors, several artisans have shown that an epitaxial channel can significantly reduce the threshold variations due to random doping fluctuations. Representative publications include Takeuchi, K., et al., “Channel engineering for the reduction of random-dopant-placement-induced threshold voltage fluctuation,” Electron Devices Meeting, 1997. IEDM '97. Technical Digest., International, pp. 841-844, 7-10 Dec 1997 and Asenov, A., Saini, S., “Suppression of random dopant-induced threshold voltage fluctuations in sub-0.1-μm MOSFETs with epitaxial and 6-doped channels,” Electron Devices, IEEE Transactions on, vol. 46, no. 8, pp. 1718-1724, Aug 1999.

For very small transistors, variations in threshold voltage due to random doping variations are inevitable because the uncertainty in any group of N items, ionized doping ions in this case, is approximately N^{1/2}. For an ensemble of 10⁶ or 10⁸ ions, the N^{1/2} uncertainty is 10³ or 10⁴ respectively, small (<1%) compared to the overall number of doping ions. However, for nanometer scale transistors, the depleted volume is in the range of 5×10⁻¹⁸ cm³. If the doping level is 10¹⁹/cm³, the mean number of active dopants is about 50, and the standard deviation in that number is just over 7. That represents an uncertainty of 14%. Modern transistors use high-K gate stacks and gate work function engineering to allow the use of lightly doped substrate which reduces the impact of the doping uncertainties. The impact of uncertainty due to variation in number of dopant atoms still continues to pose a challenge because the impact becomes more important as transistors get smaller. As long as FinFET or TriGate transistors are manufactured with fins that are free of doping, they are highly immune to threshold variations arising from the random dopant variations. Work function engineering has made that feasible for some ranges of threshold voltages, but if higher threshold voltages are required, doping the fins becomes necessary. Once the fins are doped, the N^{1/2} problem comes to the fore. The understanding that has come from analysis of planar epitaxial MOSFETs shows that providing distance of approximately 10 nm between the gate-to-channel interface and the ionized charges in the bulk mitigates the effect of random doping variations, substantially reducing the resulting variations in threshold voltage.

FIGS. 1a through 1d show prior art schematic representations of four representative classes of three-dimensional transistors. In each case the cross section represents the zone between the source and drain and beneath the gate, i. e., the active channel. Current would flow perpendicular to the plane of these diagrams. FIG. 1a shows a TriGate transistor in which the fin actually contacts the substrate 10, penetrating the isolation oxide 11. The region identified as 13 is the active fin, which may be undoped or doped to a level that sets the appropriate threshold voltage. The active fin 13 is surrounded by a gate dielectric 16, which is typically a high-K gate stack. The gate electrode 17 is normally a metal chosen for its work function, one of the key factors in defining the threshold voltage. Finally, the region 18 represents a deposited layer that provides both electrical contact and protection for the metal gate 17. Region 17 is typically amorphous silicon. Typical materials for the metal gate include TiN, but many other materials are being used or considered.

FIG. 1b shows a FinFET in which the active fin's cross section 13 resembles a triangle, and it is connected to the substrate 10. This transistor structure is completed by the isolation oxide 11, a high-K gate stack 16, a metal gate 17 and a gate connection 18, typically amorphous silicon.

FIG. 1c shows an alternative TriGate structure, but the fin 13 is fully isolated from the substrate 10 by a buried oxide 12 because this is an SOI TriGate FET. The balance of the structure resembles FIGS. 1a and 1b, with a high-K gate stack 16, a metal gate 17 and a gate contacting layer 18.

FIG. 1d shows a more classical SOI FinFET, because the nitride cap 14 on the fin 13 assures that conducting channels in the active transistor are confined to the vertical walls of the fin 13. The structure includes the substrate 10, a buried oxide 12, a high-K gate stack 16, a metal gate 17 and a gate contactor 18.

As the advantages of epitaxial transistors are not provided by the prior art, it would be advantageous to bring the benefits of epitaxial transistors to FinFETs and TriGates.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention will be apparent from the following detailed description taken in conjunction with the accompanying drawings.

FIGS. 1a-1d present schematic cross sections of four conventional FinFETs, representing the regions of their gates.

FIGS. 2a-2d present the schematic cross sections of four FinFETs realized in accordance with an embodiment that represent the regions of their respective gates.

FIG. 3 is a schematic representation of conventional SOI fins, which are typically very lightly doped.

FIGS. 4a and 4b are schematic representations of realizing this invention on an SOI substrate according to a first embodiment.

FIGS. 5a and 5b are schematic representations of realizing this invention on a bulk substrate according to a second embodiment.

FIGS. 6a-6c are schematic representations of an alternative method of realizing this invention on a bulk substrate according to a third embodiment.

FIG. 7 is a schematic cross section perpendicular to the substrate plane and aligned in the direction of current flow showing an example of a completed transistor fin.

### DETAILED DESCRIPTION OF THE PREFERRED EMBODIMENTS

The embodiments disclosed by the invention are only examples of the many possible advantageous uses and implementations of the innovative teachings presented herein. In general, statements made in the specification of the present application do not necessarily limit any of the various claimed inventions. Moreover, some statements may apply to some inventive features but not to others. In general, unless otherwise indicated, singular elements may be in plural and vice versa with no loss of generality. In the drawings, like numerals refer to like parts through several views.

An improved fin field-effect transistor (FinFET) is built on a compound fin, which has a doped core and lightly doped epitaxial channel region between that core and the gate dielectric. The improved structure reduces FinFET random doping fluctuations when doping is used to control threshold voltage. Further, the transistor design affords better source and drain conductance when compared to prior art FinFETs. Three representative embodiments of the key structure are described in detail.

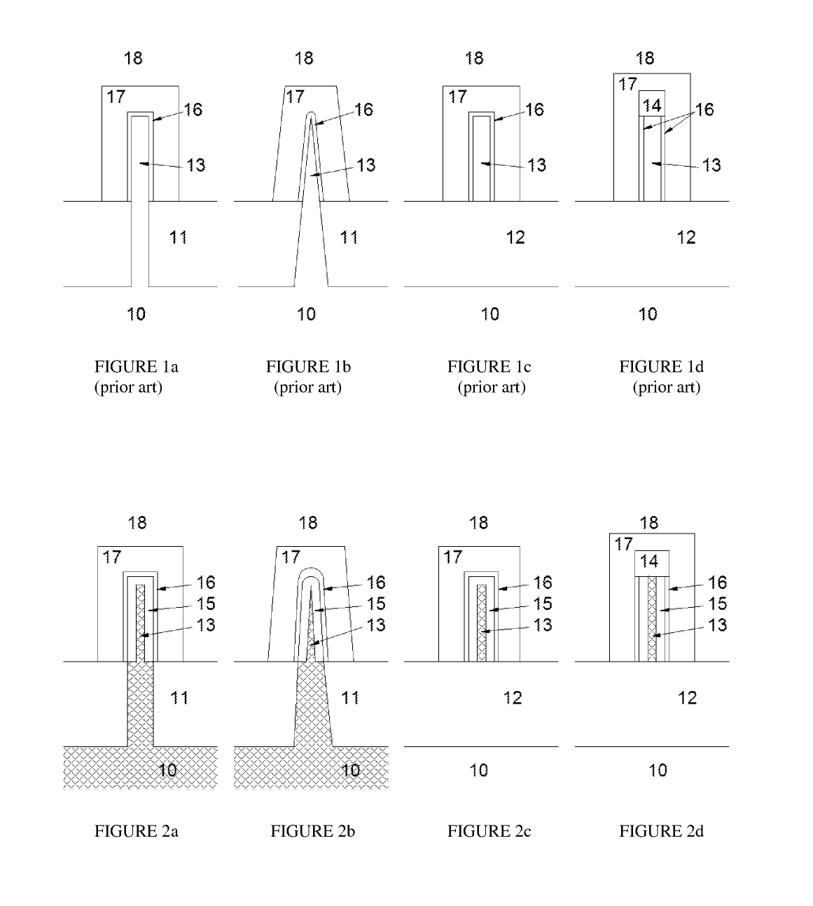

FIGS. 2a through 2d show schematic cross sections of improved FinFETs according to embodiments discussed herein. These sections are perpendicular to current flow, and they represent the region beneath the gate in the active channel. Each of transistors differs from the prior art in having a composite fin. The center of each fin is a highly doped core 13, and this core is surrounded by an undoped epitaxial layer 15, which is referred to herein as the Channel Epitaxy. The doping of the core is P-type for an NMOS transistor and N-type for a PMOS transistor. Further, the doping density of the fin cores provides one more variable that is used to adjust the threshold voltage to a desired value. In general, the core doping is used to increase the threshold voltage. FIG. 2 shows four different realizations, exemplary and non-limiting FIG. 2a depicting a fin that is connected to the substrate and a three-sided gate; exemplary and non-limiting FIG. 2b showing a triangular fin; exemplary and non-limiting FIG. 2c showing a silicon on insulator (SOI) fin having a three-sided gate; and, exemplary and non-limiting FIG. 2d depicting a gate that is effective only on the vertical walls of the fin.

To clarify the cross sections, additional explanation is provided with respect of FIG. 2b, that depicts a TriGate transistor in which the fin core 13 is connected to the substrate 10, penetrating through the isolation oxide 11. The doped fin core 13 is surrounded by an undoped epitaxial layer 15, the Channel Epitaxy. Region 16 covering the Channel Epitaxy 15 is the gate dielectric, which is typically a high-K dielectric stack, implying that its effective dielectric constant is, typically, greater than 6. The gate electrode 17 is typically a metal, metal alloy or metallic compound (herein “metal” gate), chosen for its work function. Finally, region 18 is a deposited material, typically amorphous silicon, which provides connection to and protection for the metal gate 17. The threshold voltage of this class of transistor is mainly determined by the doping of the fin core 13, by the thickness and dielectric constant of the gate stack 16, and by the work function of the gate conductor 17. One of ordinary skill-in-the-art would be able to apply the above teaching also to FIGS. 2a, 2c, and 2d without undue burden.

As would be readily understood by an artisan, the teachings herein provide the benefits of epitaxial transistors that complement the basic prior art FinFET processes. It should be understood that there are a plurality of ways to implement the epitaxial FinFET taught herein, providing its specific benefits. In the descriptions that follow, it will be assumed that standard FinFET processing is prior art and understood.

Three embodiments are described below which realize the profiles shown in FIG. 2 in the active channel region. For purposes of simplicity, the most appropriate reference profiles are those shown in FIGS. 2a and 2c for bulk FinFETs and SOI FinFETs respectively. Each of the embodiments prepares the fin doping cross section as part of initially forming the fins.

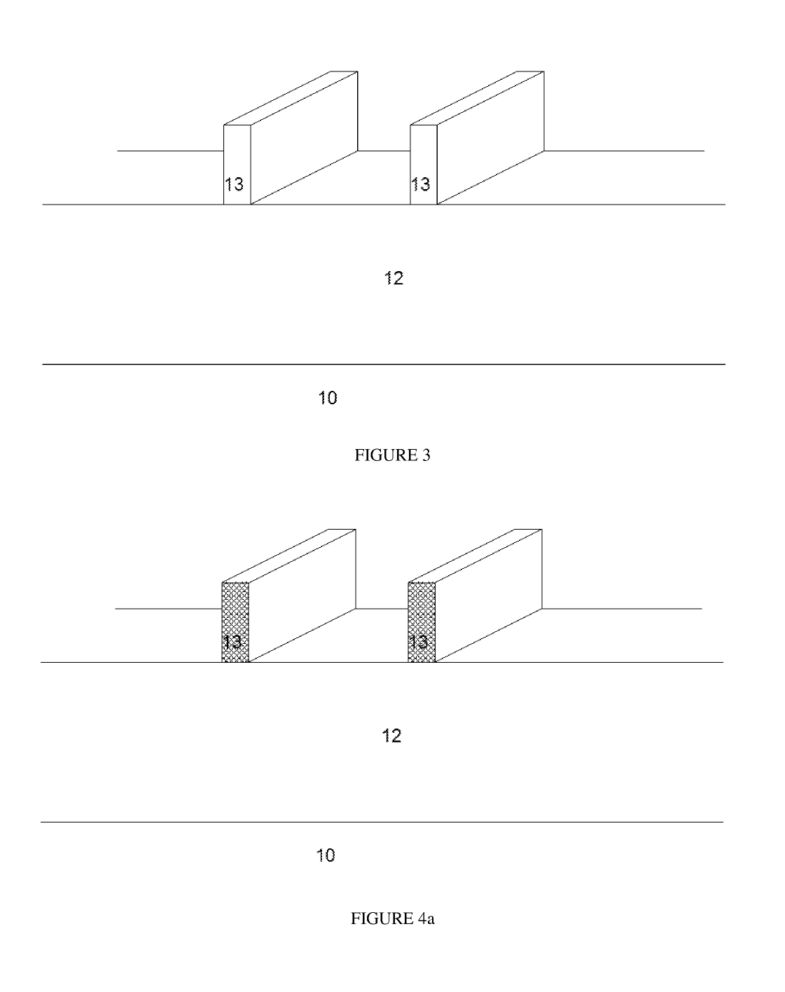

In the FinFET class of technologies, the immediate transistor substrate is typically an array of fins. One example of such a starting substrate is shown in exemplary and non-limiting FIG. 3, a case where a minimal array of two single crystal silicon fins 13 lie on top of an oxide 12, which is conventionally called a buried oxide or BOX. The BOX 12 isolates the active devices from the substrate 10. The formation of transistors on these fins corresponds to FIGS. 1c and 2c. The scope if this invention covers the fins from which the improved transistors may be fabricated by subsequent steps that are outside the scope of this invention. This invention applies to both gate-first and gate-last transistors which may be fabricated by subsequent steps that are generally known to those skilled in the art of engineering FinFETs.

### EXEMPLARY EMBODIMENT 1

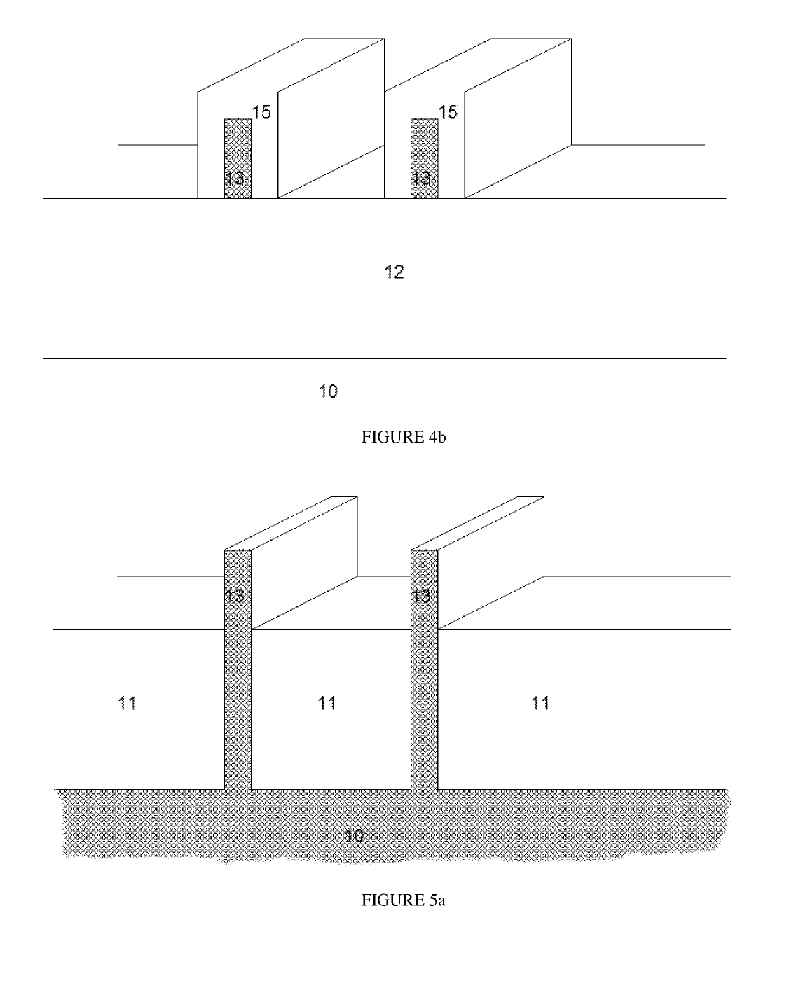

In a first exemplary and non-limiting embodiment the configuration is similar to FIG. 3, with a substrate 10 and a buried oxide 12. The fins 13 as shown in FIG. 4a are processed from the fins in FIG. 3, but rather than being lightly doped, less than 10¹⁷/cm³ as in prior art low fluctuation transistors, they are highly doped by intention, and they will become cores for the final fins. The high doping the cores of these fins adjusts the threshold voltage of the fins to a desired high value. The fin cores are 5 nm to 15 nm thick, typically 10 nm, and they are doped with donors (for a PMOS device) or acceptors (for an NMOS device) to a density of 10¹⁸/cm³ to 10²⁰/cm³. Alternatively, the highly doped fins in FIG. 4a may be formed from a highly doped layer, meaning that the heavy doping occurs before the fins are etched. For SOI fins, doping first is probably more convenient. After forming the highly doped fin cores 13, an undoped or lightly doped layer 15 of epitaxial silicon, silicon-germanium or other semiconductor is grown over the highly doped core to sheath that fin core to a predetermined thickness. This is shown in exemplary and non-limiting FIG. 4b. The typical final thickness of the undoped epitaxial sheathing layer is in the range of 5 nm to 15 nm, and it should be grown at a low temperature, less than 650° C. Lightly-doped means a doping density less that 10¹⁷ ions/cm³, and preferably below 10¹⁶ ions/cm³. Note that the exemplary and non-limiting silicon thicknesses cited herein represent final thickness targets, and the actual intermediate thicknesses may be different to allow for the thinning effects of oxidation steps in the process sequence. The combination described herein, a highly doped core with a lightly doped channel epitaxy, significantly reduces the ability of random dopant distributions to vary the threshold voltage. The efficacy of this effect is strongly dependent upon the doping density gradient between the core and the channel epi; maintaining low temperatures in all processes is essential to achieving the best performance

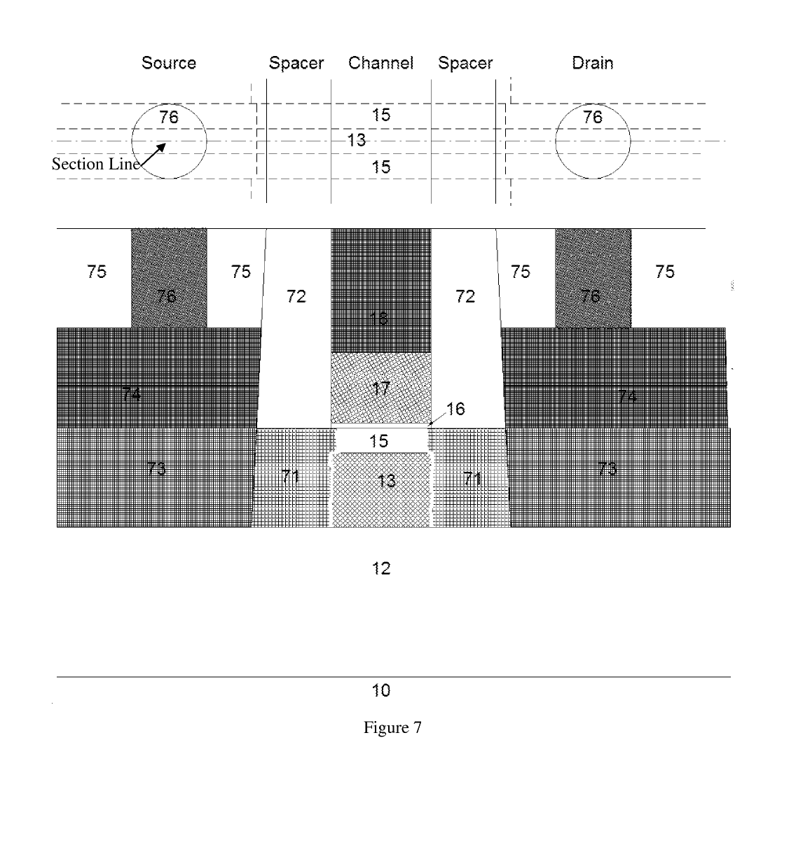

From this point forward, processing proceeds according to well-known FinFET procedures. This is illustrated using FIG. 7, which is a vertical cross section through a typical fin, oriented in the direction of current flow. These procedures include, for example, steps of forming either a protective oxide or a gate oxide, forming a gate, which may be later sacrificed, and implanting the source/drain regions 71 that will be immediately adjacent to the active channel, frequently known as drain extensions. Next, there are sidewall spacers 72 formed adjacent to the initial gate (which may or may not be sacrificed later in the process), and then the high conductivity sources and drains are created using steps that may include heavy implant doses 73, metal silicide formation or epitaxial enhancement 74, singly or in combination. A first inter-layer dielectric 75 is deposited, and then planarized with CMP, exposing the initial gate. For a gate last structure, the initial gate and its underlying protective oxide are etched away, then replaced with a high-K gate stack 16, meaning a gate dielectric with an effective dielectric constant in excess of 6, and a metal gate 17 with a controlled work function. The metal gate is generally contacted with a robust gate handle, identified as 18 in FIGS. 2 and 7. The transistor is completed with a second interlayer dielectric (not shown), contacts 76 and interconnect (not shown). This example includes the substrate 10 and a buried isolation oxide 12, as well as the channel core 13 and the epitaxial sheath 15.

While gate-first transistor structures may use polysilicon to form the electrically active gate, metal gates are commonly used for advanced technologies. The improvements effected by the combination of highly doped fin core sheathed by a very lightly doped channel epitaxial layer apply to all gate structures.

### EXEMPLARY EMBODIMENT 2

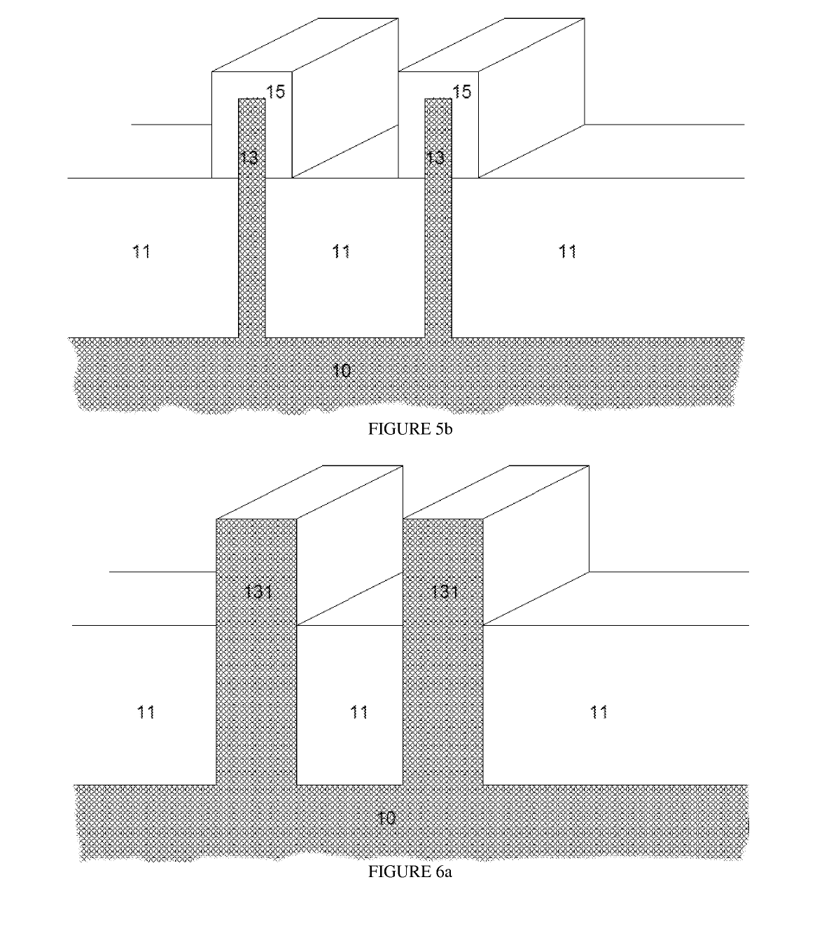

In the second exemplary and non-limiting embodiment the fins are formed from the substrate 10, as illustrated in exemplary and non-limiting FIG. 5a. The isolation oxide 11 between the fins provides a platform upon which the transistors are formed. The fins 13 in FIG. 5a are highly doped by intention to become cores for the final fins. The fin cores 13 are 5 nm to 15 nm thick, typically 10 nm, and they are doped with donors (for a PMOS device) or acceptors (for an NMOS device) to a density of 10¹⁸/cm³ to 10²⁰/cm³. This doping can be done either before or after the fin cores are formed. After forming the highly doped fin cores 13, the fins are expanded by growing an undoped or lightly doped layer 15 of epitaxial silicon, silicon-germanium or other semiconductor as a sheath over the highly doped core. This is shown in exemplary and non-limiting FIG. 5b. The undoped epitaxial layer has a typical final thickness in the range of 5 nm to 15 nm, and it should be grown at a low temperature, less than 650° C. Lightly-doped means a doping density less that 10¹⁷ ions/cm³, and preferably below 10¹⁶ ions/cm³. Note that the exemplary and non-limiting silicon thicknesses cited here represent final thickness targets, and the actual intermediate thicknesses may be different to allow for the thinning effects of oxidation steps in the process sequence. The combination described here, a highly doped core with a lightly doped channel epitaxy, significantly reduces the ability of random dopant distributions to vary the threshold voltage. The efficacy of this effect is strongly dependent upon the doping density gradient between the core and the channel epi; maintaining low temperatures in all processes is essential to achieving the best performance.

From this point forward, processing proceeds according to well-known FinFET procedures. These steps were summarized in Embodiment 1, and the sequence for Embodiment 2 is the same. Unlike the SOI configuration in Embodiment 1, the substrate connection offers an opportunity to further control threshold voltages with bias on the substrate 10.

### EXEMPLARY EMBODIMENT 3

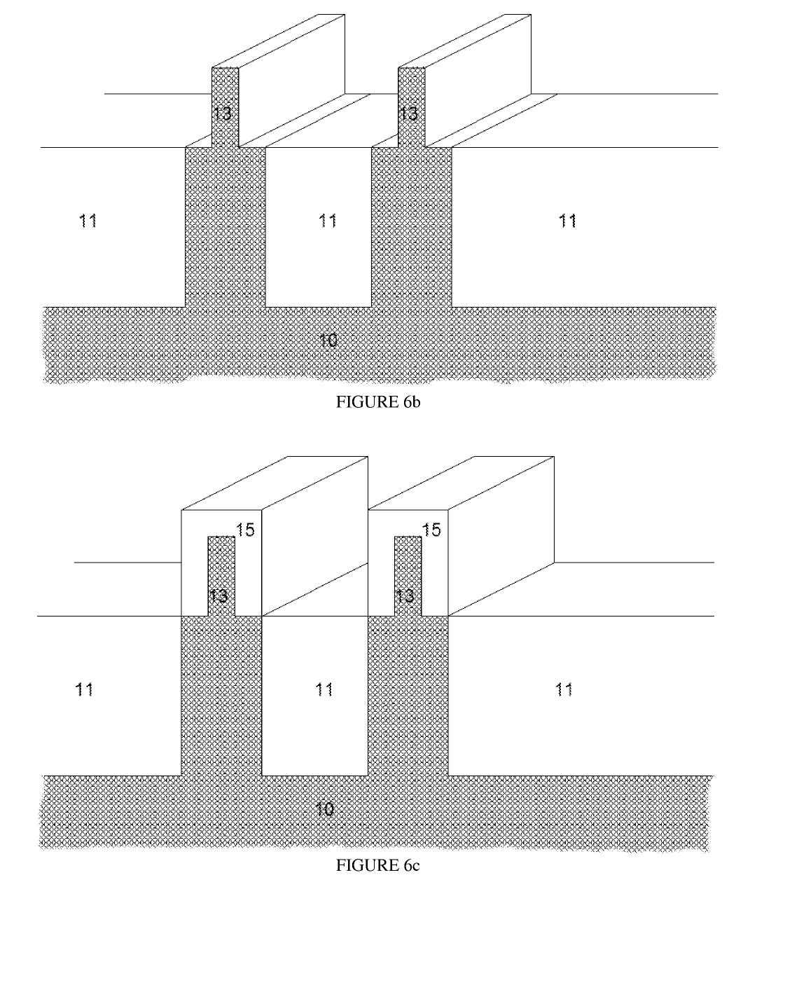

In the third exemplary and non-limiting embodiment the initial fins 131 are also formed from the substrate 10, as illustrated in FIG. 6a. Between the initial fins 131 the isolation oxide 11 provides a platform upon which the transistors are formed. The initial fins 131 in FIG. 6a are highly doped by intention, but they are wider than the fin cores 13 in Embodiment 2 as they are subject to additional processing. The initial fins 131 are 15 nm to 50 nm thick, typically 30 nm, and they are doped with donors (for a PMOS device) or acceptors (for an NMOS device) to a density of 10¹⁸/cm³ to 10²⁰/cm³. The doping in the fins is determined by the desired threshold voltage. This doping can be done either before or after the initial fins are formed. The next step, shown in exemplary and non-limiting FIG. 6b, is an etching step that removes a portion of the initial fins 131 to leave fin cores 13, which are typically 5 nm to 15 nm wide. After the etching step leaves the highly doped fin cores 13, the fin cores are expanded by growing an undoped or lightly doped layer 15 of epitaxial silicon, silicon-germanium or other semiconductor that sheaths the highly doped core. This is shown in exemplary and non-limiting FIG. 6c. Typically, the undoped epitaxial layer has a final thickness in the range of 5 nm to 15 nm, and it should be grown at a low temperature, less than 650° C. Lightly-doped means a doping density less that 10¹⁷ ions/cm³, and preferably below 10¹⁶ ions/cm³. Note that the exemplary and non-limiting silicon thicknesses cited here represent final thickness targets, and the actual intermediate thicknesses may be different to allow for the thinning effects of oxidation steps in the process sequence. The combination described here, a highly doped core with a lightly doped channel epitaxy, has been shown to significantly reduce the ability of random dopant distributions to vary the threshold voltage. The efficacy of this effect is strongly dependent upon the doping density gradient between the core and the channel epi; maintaining low temperatures in all processes is essential to achieving the best performance.

From this point forward, processing proceeds according to well-known FinFET procedures. These steps were summarized in Embodiment 1, and the sequence for Embodiment 2 is the same. Unlike the SOI configuration in Embodiment 1, the substrate connection offers an opportunity to further control threshold voltages with bias on the substrate 10.

It should be noted that in all the above embodiments the heavy doping in the core of the fin is of the polarity opposite to that of the source and drain regions. For instance, the core doping of fins for NMOS is done with boron atoms. This heavily boron doped region extends over the whole length of the fin. Except for the channel region, this boron doped region has to be overcompensated to create a low resistance path to source and drain. This is done by implanting the source drain region with doping well exceeding the core doping in the region where contacts are formed. The presence of core under the source drain extension region actually helps keep the junction in the extension region shallow and hence improve short channel effect in the MOSFET.

While FIGS. 3 through 6 all represent a schematically preferred TriGate form of the

FinFET, all of the embodiments are equally applicable to FinFET configurations that use a dielectric cap, typically silicon nitride, to passivate the top region of the fin, assuring that active channels are only formed on the vertical walls of the fins. Further they are applicable to FinFET configurations in which the fin's cross section resembles a triangle.

These embodiments discussed herein offer several advantages over prior art FinFETs:

a) Compared to a standard FinFET with a doped fin, the threshold voltage fluctuations are reduced;

b) Because the final fins are composed of a core and a sheath, their cross sections are from 3 to 10 times wider than conventional fins, and this makes it possible to reduce the parasitic resistance in the sources and drains; and,

c) Embodiments 2 and 3 both connect to the substrate in a way that makes modulating the threshold voltage by substrate bias practical.

All examples and conditional language recited herein are intended for pedagogical purposes to aid the reader in understanding the principles of the invention and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure. A person of ordinary skill-in-the-art would readily understand that the invention can be adapted for use in a plurality of ways, including integrated circuits where all transistors or a portion thereof are manufactured using the techniques disclosed hereinabove. Furthermore, although the invention is described herein with reference to specific embodiments, one skilled-in-the-art will readily appreciate that other applications may be substituted for those set forth herein without departing from the spirit and scope of the present invention. Accordingly, the invention should only be limited by the Claims included below.

What is claimed is:

1. A transistor formed on a fin comprising:
a fin core having a first doping density; and
a channel region covering the fin core, the channel region having a second doping density that is less than the first doping density.

2. The transistor of claim 1, wherein the first doping density is between 10¹⁸/cm³ and 10²⁰/cm³ of donors for a PMOS transistor and acceptors for an NMOS transistor.

3. The transistor of claim 1, wherein the second doping density is less than 10¹⁷/cm³.

4. The transistor of claim 1, wherein the second doping density is less than 10¹⁶/cm³.

5. The transistor of claim 1, further comprising:
a stack of dielectric materials on the channel region.

6. The transistor of claim 5, wherein the stack of dielectric materials has an effective dielectric constant larger than 6.

7. The transistor of claim 1, further comprising a gate over the channel region, wherein the gate material is one of: a metal, metal alloy or metallic compound.

8. The transistor of claim 1 wherein the channel region is an epitaxial sheathing layer, and the final thickness of the epitaxial sheathing layer is in the range of 5 nm to 15 nm.

9. The transistor of claim 1 wherein the fin is formed on a silicon wafer.

10. The transistor of claim 1 wherein the fin is a silicon-on-insulator fin.

11. A transistor formed on a fin comprising:
a fin core having a first doping density;
an epitaxial layer on the fin core, the epitaxial layer having a second doping density that is less than the first doping density;
source and drain regions formed in the epitaxial layer, the source and drain regions being separated to define a channel region between the source and drain regions;
a dielectric layer on the channel region; and
a gate on the dielectric layer.

12. The transistor of claim 11, wherein the first doping density is between 10¹⁸/cm³ and 10²⁰/cm³ of donors for a PMOS transistor and acceptors for an NMOS transistor.

13. The transistor of claim 11, wherein the second doping density is less than 10¹⁷/cm³.

14. The transistor of claim 11, wherein the second doping density is less than 10¹⁶/cm³.

15. The transistor of claim 11, wherein the dielectric layer comprises a stack of dielectric materials having an effective dielectric constant larger than 6.

16. The transistor of claim 11, wherein the gate material is one of: a metal, metal alloy or metallic compound.

17. The transistor of claim 11 wherein the final thickness of the epitaxial layer is in the range of 5 nm to 15 nm.

18. The transistor of claim 11 wherein the fin is formed on a silicon wafer.

19. The transistor of claim 11 wherein the fin is a silicon-on-insulator fin.

20. The transistor of claim 11 wherein the source and drain regions each include source and drain extensions, respectively, formed in the epitaxial layer, the source and drain extensions being separated to define the channel region between the source and drain extensions.

21. A method formed on a fin comprising:
a) providing a fin core having a first doping density;
b) forming an epitaxial layer on the fin core, the epitaxial layer having a second doping density that is less than the first doping density;
c) forming an oxide on the epitaxial layer;
d) forming a gate on the epitaxial layer;
e) implanting source and drain extensions;
f) forming sidewall spacers adjacent the gate;
g) forming source and drains using implants, metal silicide formation or epitaxial enhancement or a combination of implants, metal silicide formation or epitaxial enhancement;
h) depositing a first inter-layer dielectric and planarizing to expose the gate.

22. The method of claim 21 wherein the oxide formed in c) is a gate oxide.

23. The method of claim 21 further comprising:
i) removing the gate formed in d) and the oxide between the sidewall spacers formed in c);
j) forming a dielectric between the spacers;
k) forming a metal gate over the dielectric.

24. The method of claim 23 further comprising forming a gate handle over the metal gate.

25. The method of claim 23 wherein the dielectric formed in j) is a high-K dielectric is a dielectric stack having a dielectric constant in excess of 6.

26. The method of claim 23, wherein the first doping density is between 10¹⁸/cm³ and 10²⁰/cm³ of donors for a PMOS transistor and acceptors for an NMOS transistor.

27. The method of claim 23, wherein the second doping density is less than 10¹⁷/cm³.

28. The method of claim 23, wherein the second doping density is less than 10¹⁶/cm³.

29. The method of claim 23 wherein the fin is formed on a silicon wafer.

30. The method of claim 23 wherein the fin is a silicon on insulator fin.

31. The method of claim 21 wherein the epitaxial layer of b) is grown at a temperature of less than 650° C.

32. The method of claim 21 wherein all processes after a) are performed at temperatures of less than 650° C.
